(19) United States
(12) Patent Application Publication
(10) Pub. No.: US 2025/0125193 A1
(43) Pub. Date: Apr. 17, 2025

(54) SELF-ALIGNED TOPVIA AND METAL LINE WITH INCREASED HEIGHT

(71) Applicant: INTERNATIONAL BUSINESS MACHINES CORPORATION, ARMONK, NY (US)

(72) Inventors: Koichi Motoyama, Clifton Park, NY (US); Ruilong Xie, Niskayuna, NY (US); Christopher J. Penny, Saratoga Springs, NY (US); Hosadurga Shobha, Niskayuna, NY (US); Nicholas Anthony Lanzillo, Wynantskill, NY (US); John Christopher Arnold, North Chatham, NY (US); Kisik Choi, Watervliet, NY (US)

(21) Appl. No.: 18/484,470

(22) Filed: Oct. 11, 2023

(51) Int. Cl. H01L 21/768; H01L 23/522; H01L 23/532

(52) U.S. Cl. CPC H01L 21/7682; H01L 21/76834; H01L 21/7684; H01L 21/76877; H01L 23/5226; H01L 23/53266

(57) ABSTRACT

Embodiments of present invention provide an interconnect structure. The interconnect structure includes a first metal line having a lower portion and an upper portion of different material composition, sidewalls of the lower portion of the first metal line being vertically aligned with sidewalls of the upper portion of the first metal line; a second metal line having a lower portion and an upper portion of different material composition, sidewalls of the lower portion of the second metal line being vertically aligned with sidewalls of the upper portion of the second metal line; a dielectric liner lining sidewalls of the lower and upper portions of the first metal line and sidewalls of the lower and upper portions of the second metal line; and an isolation layer between the first and second metal lines, the isolation layer including an airgap. A method of forming the same is also provided.

### BACKGROUND

The present application relates to manufacturing of semiconductor integrated circuits. More particularly, it relates to method of forming metal line and topvia with increased height and the structure formed by the method.

As semiconductor industry moves towards smaller node, for example 5-nm node and beyond, instead of conventional copper (Cu), alternative metals such as ruthenium (Ru) is expected to be used for forming the minimum pitch local interconnects because of smaller resistivity size effect, less stringent barrier/liner need, and better reliability performance when being compared with Cu. To further reduce line resistance of interconnects formed by the alternative metals, one of the common approaches is to increase height of the metal lines. However, with interconnects being formed through a subtractive patterning scheme, increasing height of the metal lines brings several process challenges. For example, one of these process challenges is incomplete etch of the alternative metals caused by hard mask clogging during etching. The incomplete etch consequently results in short issue between formed metal lines.

### SUMMARY

Embodiments of present invention provide an interconnect structure. The structure includes a metal line having a lower portion and an upper portion of different material composition, sidewalls of the lower portion of the metal line being vertically aligned with sidewalls of the upper portion of the metal line; and a dielectric liner lining the sidewalls of the lower portion of the metal line and the sidewalls of the upper portion of the metal line.

In one embodiment, the lower portion of the metal line includes ruthenium of more than 99 at. % with a first impurity level and the upper portion of the metal line includes ruthenium of more than 95 at. % but less than 99 at. % with a second impurity level, where the second impurity level is larger than the first impurity level.

In another embodiment, the lower portion of the metal line is formed by a physical vapor deposition (PVD) process and the upper portion of the metal line is formed by a chemical vapor deposition (CVD) process.

According to one embodiment, the structure further includes a dielectric layer covering a top surface of the upper portion of the metal line, sidewalls of the dielectric layer being vertically aligned with the sidewalls of the upper portion of the metal line, where the dielectric liner lines the sidewalls of the dielectric layer.

According to another embodiment, the structure further includes a topvia on top of the upper portion of the metal line, where the topvia has a same material composition as the upper portion of the metal line and has a top surface that is co-planar with a top surface of the dielectric layer.

In one embodiment, the metal line is a first metal line, and the structure further includes a second metal line separated from the first metal line by an isolation layer, where the isolation layer has a top surface that is co-planar with the top surface of the topvia and has an aspect ratio of height over width that ranges from about 15 to about 20.

In another embodiment, the isolation layer has a width equal to or less than 10 nm; the lower portion of the first metal line has a thickness between about 80 nm and about 100 nm; the upper portion of the first metal line has a thickness between about 40 nm and about 50 nm; and the topvia has a height larger than 10 nm.

In yet another embodiment, the isolation layer includes an airgap.

Embodiments of present invention provide a method of forming an interconnect structure. The method includes forming a conductive layer of a first metal on top of a substrate; patterning the conductive layer into a lower portion of a first metal line and a lower portion of a second metal line; creating a first and a second opening aligned respectively with the lower portion of the first metal line and the lower portion of the second metal line; and filling the first and the second opening with a second metal to form a raw upper portion of the first metal line and a raw upper portion of the second metal line.

According to one embodiment, the method further includes recessing a portion of the raw upper portion of the first metal line to form an upper portion of the first metal line and a topvia on top of the upper portion of the first metal line; and recessing a portion of the raw upper portion of the second metal line to form an upper portion of the second metal line.

According to another embodiment, the method further includes forming a dielectric layer on top of the upper portion of the first metal line; and planarizing a top surface of the dielectric layer to be co-planar with a top surface of the topvia.

In one embodiment, patterning the conductive layer includes forming a hard mask on top of the conductive layer; and selectively removing portions of the conductive layer not covered by the hard mask to form the lower portion of the first metal line and the lower portion of the second metal line.

In another embodiment, creating the first and the second opening includes depositing an isolation layer on top of the substrate to surround the lower portion of the first metal line and the hard mask on top thereof and to surround the lower portion of the second metal line and the hard mask on top thereof; selectively removing the hard mask above the lower portion of the first metal line to create the first opening; and selectively removing the hard mask above the lower portion of the second metal line to create the second opening.

In yet another embodiment, depositing the isolation layer includes forming an airgap inside the isolation layer between the first metal line and the second metal line.

According to one embodiment, the method further includes forming a dielectric liner lining sidewalls of the lower portion of the first metal line and the hard mask on top thereof; and lining sidewalls of the lower portion of the second metal line and the hard mask on top thereof.

Embodiments of present invention further provide an interconnect structure, which includes a first metal line having a lower portion and an upper portion of different material composition, sidewalls of the lower portion of the first metal line being vertically aligned with sidewalls of the upper portion of the first metal line; a second metal line having a lower portion and an upper portion of different material composition, sidewalls of the lower portion of the second metal line being vertically aligned with sidewalls of the upper portion of the second metal line; a dielectric liner lining sidewalls of the lower portion and the upper portion of the first metal line and lining sidewalls of the lower portion and the upper portion of the second metal line; and an isolation layer between the first metal line and the second metal line, the isolation layer including an airgap.

### BRIEF DESCRIPTION OF THE DRAWINGS

The present invention will be understood and appreciated more fully from the following detailed description of embodiments of present invention, taken in conjunction with accompanying drawings of which:

FIGS. 1A and 1B are demonstrative illustrations of cross-sectional views and FIG. 1C is a simplified top view of an interconnect structure in a step of manufacturing thereof according to one embodiment of present invention;

FIGS. 2A and 2B are demonstrative illustrations of cross-sectional views and FIG. 2C is a simplified top view of an interconnect structure in a step of manufacturing thereof according to one embodiment of present invention;

FIGS. 3A and 3B are demonstrative illustrations of cross-sectional views and FIG. 3C is a simplified top view of an interconnect structure in a step of manufacturing thereof according to one embodiment of present invention;

FIGS. 4A and 4B are demonstrative illustrations of cross-sectional views and FIG. 4C is a simplified top view of an interconnect structure in a step of manufacturing thereof according to one embodiment of present invention;

FIGS. 5A and 5B are demonstrative illustrations of cross-sectional views and FIG. 5C is a simplified top view of an interconnect structure in a step of manufacturing thereof according to one embodiment of present invention;

FIGS. 6A and 6B are demonstrative illustrations of cross-sectional views and FIG. 6C is a simplified top view of an interconnect structure in a step of manufacturing thereof according to one embodiment of present invention;

FIGS. 7A and 7B are demonstrative illustrations of cross-sectional views and FIG. 7C is a simplified top view of an interconnect structure in a step of manufacturing thereof according to one embodiment of present invention;

FIGS. 8A and 8B are demonstrative illustrations of cross-sectional views and FIG. 8C is a simplified top view of an interconnect structure in a step of manufacturing thereof according to one embodiment of present invention; and

FIG. 9 is a demonstrative illustration of a flow-chart of a method of manufacturing an interconnect structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

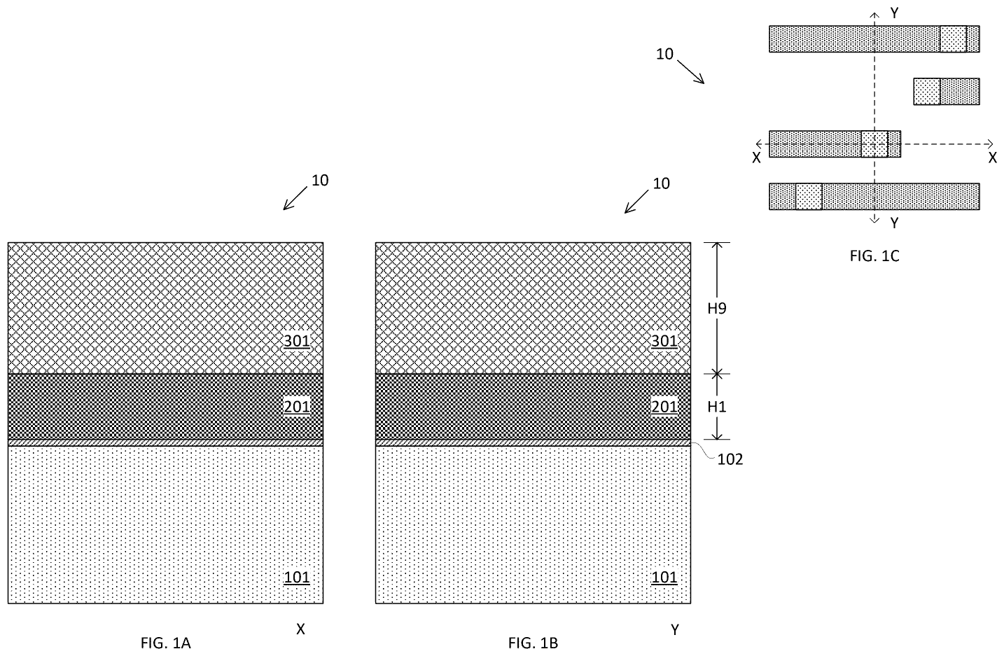

FIGS. 1A and 1B are demonstrative illustrations of cross-sectional views and FIG. 1C is a simplified top view of an interconnect structure in a step of manufacturing thereof according to one embodiment of present invention. More specifically, FIG. 1A illustrates a cross-sectional view of an interconnect structure along a dashed line X as is indicated in FIG. 1C. In other words, the cross-section illustrated in FIG. 1A is made along the length or length direction of a metal line. FIG. 1B illustrates a cross-sectional view of the interconnect structure along a dashed line Y as is indicated in FIG. 1C. In other words, the cross-section illustrated in FIG. 1B is made along the width or width direction of the metal line. FIG. 1C illustrates a simplified top view of a metal layer containing at least the metal line and one or more additional metal lines, vias, and/or topvias. Because FIG. 1C is mainly used to illustrate locations of the cross-sections shown in FIGS. 1A and 1B, only key features and elements of the metal layer may be illustrated, already formed or to be formed, and other elements such as for example dielectric liner may not necessarily be shown in order not to overcrowd the drawing, and to the extent that their omission from FIG. 1C does not hinder the description of embodiments of present invention, even though these elements do exist as well.

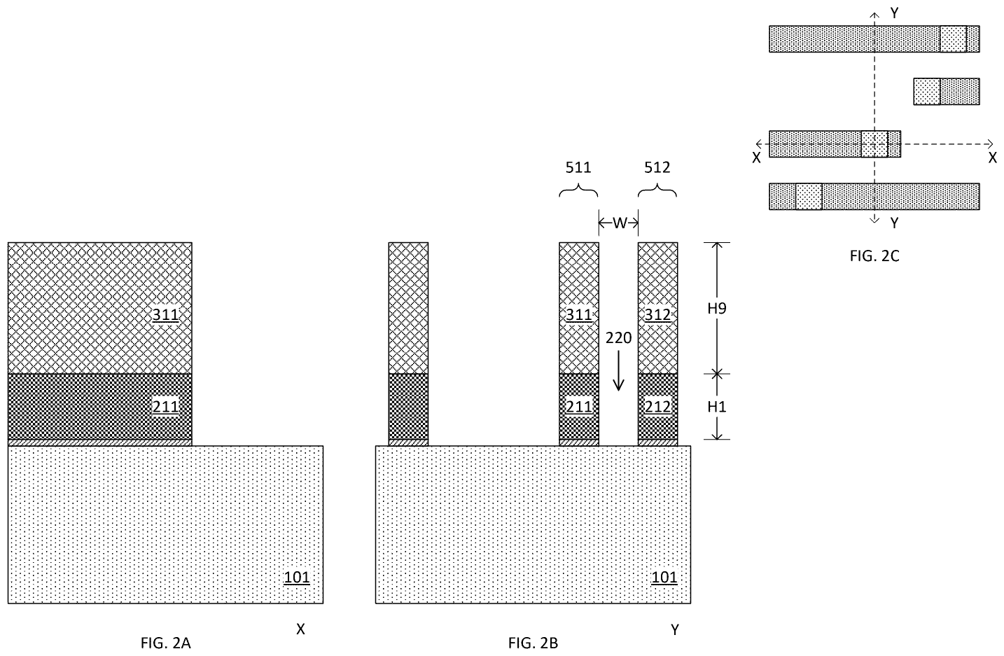

Similarly, FIGS. 2A, 2B, and 2C to FIGS. 8A, 8B, and 8C illustrate cross-sectional views and simplified top views of the interconnect structure, at various manufacturing stages, in manners similar and/or corresponding to FIGS. 1A, 1B, and 1C.

Reference is made back to FIGS. 1A, 1B, and 1C. Embodiments of present invention provide forming an interconnect structure 10 that will be formed to include one or more metal lines and one or more topvias as is illustrated in FIG. 1C. More particularly, embodiments of present invention provide receiving or providing a supporting structure such as, for example, a semiconductor substrate 101 and forming a barrier layer 102 such as, for example, a tantalum nitride (TaN) on top of the semiconductor substrate 101. Embodiments of present invention further provide forming a conductive layer 201 of a first metal on top of the barrier layer 102. The conductive layer 201 may be used to form a lower portion of the one or more metal lines. The first metal may be, for example, ruthenium (Ru). However, embodiments of present invention are not limited in this aspect and the first metal may be molybdenum (Mo), rhodium (Rh), iridium (Ir), nickel (Ni), aluminum (Al), and/or other suitable metals. The conductive layer 201 of the first metal may have a first material composition.

The conductive layer 201 of the first metal may be formed through a physical vapor deposition (PVD) process. Compared with a conductive layer of a same first metal but formed through a different process such as a chemical vapor deposition (CVD) process, the conductive layer 201 formed through the PVD process may have less impurity, and thus less resistance and/or higher conductivity. For example, the conductive layer 201 may be a layer of Ru formed through a PVD process with a first impurity level and the first impurity level may be, for example, less than 1 at. % and preferably less than 0.1 at. %. In other words, the conductive layer 201 may be a layer of Ru of more than 99 at. % and preferably more than 99.9 at. %.

In forming the one or more metal lines with a width of gaps between the one or more metal lines that may be as small as about 10 nm or less, the conductive layer 201 may be deposited to have a thickness H1 (or height) ranging from about 10 nm to about 100 nm such that gaps and/or openings created in the conductive layer 201 may have an aspect ratio of height over width between 1 and 10. Generally, the conductive layer 201 may preferably be made sufficiently thick in order to reduce resistance but still below a thickness level such that in a subsequent etch process, the conductive layer 201 may be properly patterned to form metal lines without process issues such as incomplete etch. In one embodiment, the conductive layer 201 may be deposited to have a thickness between about 80 nm and about 100 nm such that the subsequent etch process may create gaps and/or openings between the formed one or more metal lines that have an aspect ratio ranging from about 8 to about 10.

Embodiments of present invention further provide forming a hard mask layer 301 on top of the conductive layer 201. The hard mask layer 301 may be formed to have a thickness H9 ranging from about 10 nm to about 100 nm. In one embodiment, a total thickness (H1+H9) of the hard mask layer 301 and the conductive layer 201 may approximately equal to a combined thickness, or height, of the (to be formed) one or more metal lines and one or more topvias on top of the one or more metal lines, as being described below in more details.

FIGS. 2A and 2B are demonstrative illustrations of cross-sectional views and FIG. 2C is a simplified top view of an interconnect structure in a step of manufacturing thereof according to one embodiment of present invention. More particularly, following the step illustrated in FIGS. 1A, 1B, and 1C, embodiments of present invention provide creating a mask pattern from the hard mask layer 301 through a lithographic patterning process. The mask pattern may include, for example, a first mask 311 and a second mask 312. The mask pattern, including the first mask 311 and the second mask 312, may subsequently be transferred into the conductive layer 201 through a selective etching process to create a lower portion of the one or more metal lines. For example, the lower portion of the one or more metal lines may include at least a lower portion 211 of a first metal line 511 and a lower portion 212 of a second metal line 512. The selective etching process may also etch or remove a portion of the barrier layer 102 until portions of the underneath semiconductor substrate 101 are exposed.

Transferring the mask pattern, such as a pattern of the first mask 311 and the second mask 312, into the conductive layer 201 may create one or more openings or gaps in the conductive layer 201 that are self-aligned to the openings or gaps in the hard mask layer 301. For example, an opening 220 or gap may be created between the lower portion 211 of the first metal line 511 and the lower portion 212 of the second metal line 512, and the opening 220 may have a width W. In one embodiment, the width W of the opening 220 may be equal to or less than 10 nm. The opening 220 in the conductive layer 210 may have an aspect ratio of height over width, denoted by H1/W, and the aspect ratio may be made up to 10 without experiencing any process issues such as incomplete etches, when the conductive layer 210 has a thickness of about 100 nm.

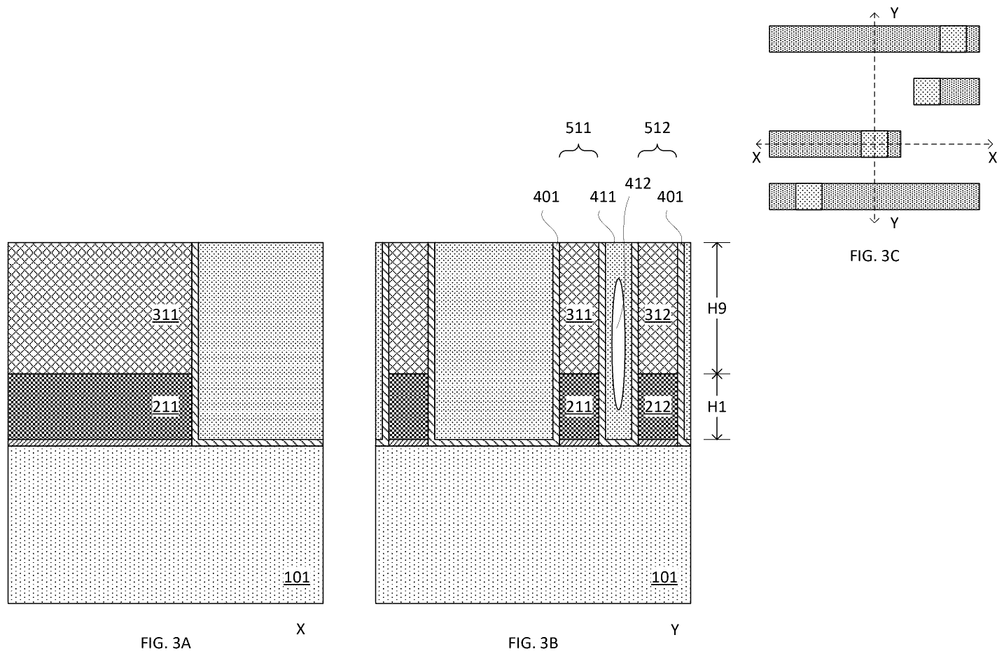

FIGS. 3A and 3B are demonstrative illustrations of cross-sectional views and FIG. 3C is a simplified top view of an interconnect structure in a step of manufacturing thereof according to one embodiment of present invention. More particularly, following the step illustrated in FIGS. 2A, 2B, and 2C, embodiments of present invention provide forming a dielectric liner 401 such as, for example, silicon-nitride (SiN) or silicon-oxide (SiO₂) lining sidewalls of the hard mask layer 301 such as the first mask 311 and the second mask 312; lining sidewalls of the lower portion 211 of the first metal line 511; lining sidewalls of the lower portion 212 of the second metal line 512; and lining the exposed top surfaces of the substrate 101 between the first metal line 511 and the second metal line 512. Embodiments of present invention further provide filling any remaining openings between the hard mask, such as the first mask 311 and the second mask 312, and the lower portions of the one or more metal lines with a dielectric material, thereby forming an isolation layer 411. For example, a portion of the isolation layer 411 may be between the first mask 311 and the second mask 312 and between the lower portion 211 of the first metal line 511 and the lower portion 212 of the second metal line 512. A chemical-mechanical-polishing (CMP) process may subsequently be applied to planarize a top surface of the isolation layer 411. The isolation layer 411 may be formed through a CVD process.

In one embodiment, because of the high aspect ratio, one or more airgaps may be formed inside the isolation layer 411 during the deposition process of the dielectric material.

For example, when the opening between the first and the second mask 311 and 312 and between the lower portion 211 of the first metal lines 511 and the lower portion 212 of the second metal line 512 has a combined aspect ratio, measured by (H1+H9)/W, and the combined aspect ratio is as high as 20, an airgap 412 may be formed inside the isolation layer 411.

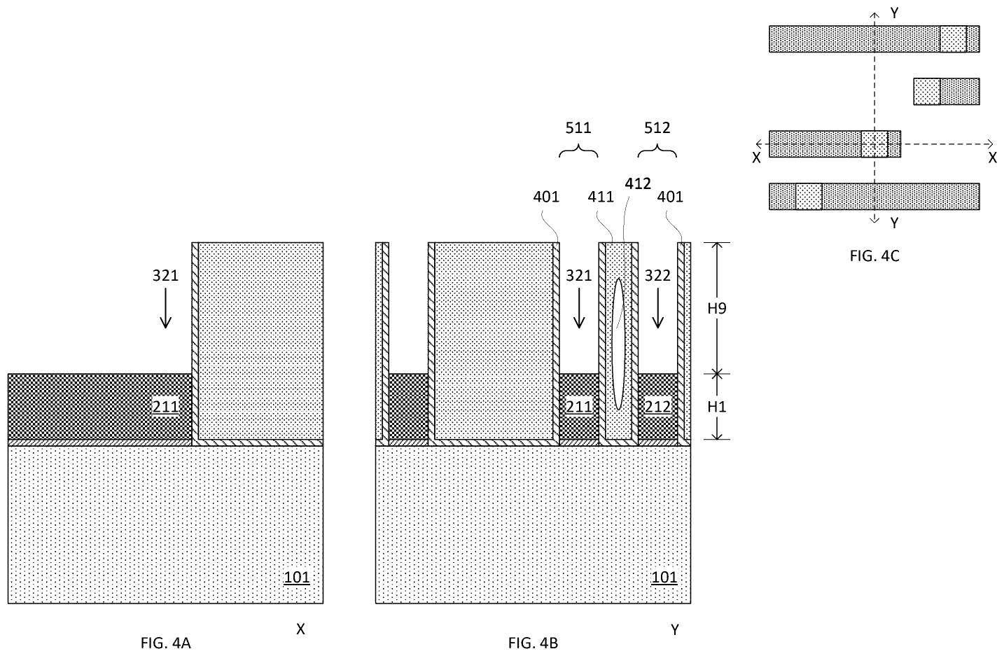

FIGS. 4A and 4B are demonstrative illustrations of cross-sectional views and FIG. 4C is a simplified top view of an interconnect structure in a step of manufacturing thereof according to one embodiment of present invention. More particularly, following the step illustrated in FIGS. 3A, 3B, and 3C, embodiments of present invention provide selectively removing the hard masks such as the first mask 311 and the second mask 312 thereby creating a first and a second opening 321 and 322, which are above and self-aligned to the lower portion 211 of the first metal line 511 and the lower portion 212 of the second metal line 512. The removal of the hard masks including the first mask 311 and the second mask 312 may be achieved through, for example, an ash process.

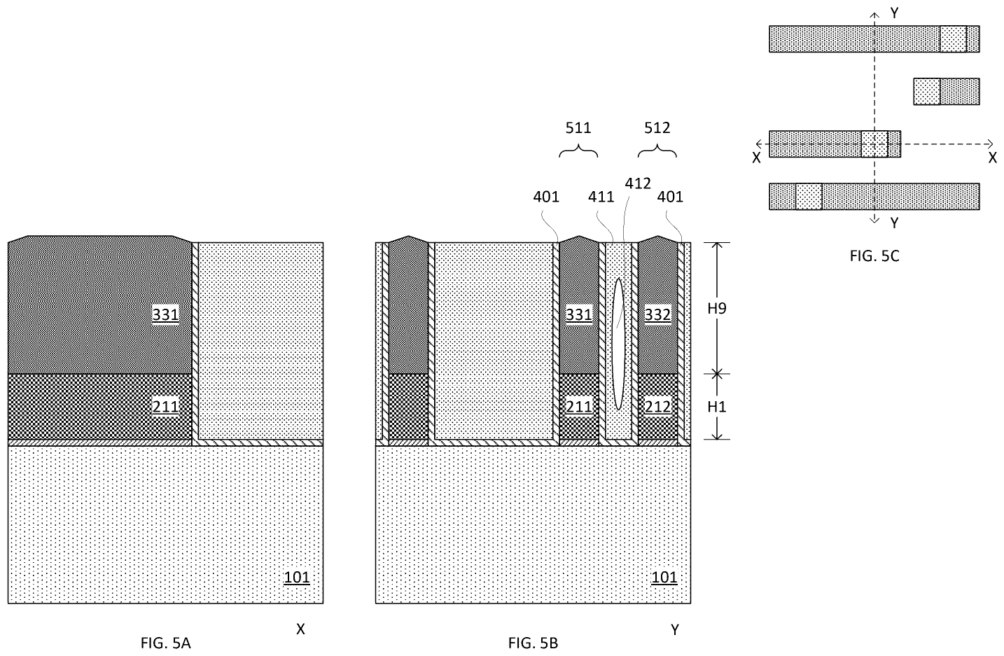

FIGS. 5A and 5B are demonstrative illustrations of cross-sectional views and FIG. 5C is a simplified top view of an interconnect structure in a step of manufacturing thereof according to one embodiment of present invention. More particularly, following the step illustrated in FIGS. 4A, 4B, and 4C, embodiments of present invention provide forming raw upper portions of the one or more metal lines such as forming a raw upper portion 331 of the first metal line 511 and a raw upper portion 332 of the second metal line 512 through, for example, a selective metal growth process of a second metal.

The second metal may be a same metal as the first metal of the lower portion 211 of the first metal line 511 and the lower portion 212 of the second metal line 512. In other words, the second metal may be Ru, Mo, Rh, Ir, Ni, Al, and other suitable metals. However, embodiments of present invention are not limited in this aspect and the second metal may have a second material composition that is different from the first material composition of the first metal.

The second metal may be selectively deposited through a CVD process, instead of a PVD process, on top of the lower portion 211 of the first metal line 511 and the lower portion 212 of the second metal line 512 between the liner 401 and in the openings 321 and 322. The CVD process may be used in order to form upper portions of the one or more metal lines, and in some instances including one or more topvias, in the openings 321 and 322, when the openings 321 and 322 may have an aspect ratio that is bigger or larger than openings that are suitable for a PVD process. Consequently, when Ru is used in the CVD process, the raw upper portion 331 of the first metal line 511 and the raw upper portion 332 of the second metal line 512 formed by the CVD process may have a second impurity level. The second impurity level may generally be larger than the first impurity level of the lower portion 211 of the first metal line 511 and the lower portion 212 of the second metal line 512. For example, the second impurity level may be 5 at. % or less and in one embodiment may be 0.5 at. % or less. In other words, the raw upper portion 331 of the first metal line 511 and the raw upper portion 332 of the second metal line 512 may be made of or contain Ru of more than 95 at. % and in one embodiment more than 99.5 at. %, but less than the Ru in the lower portion 211 of the first metal line 511 and the lower portion 212 of the second metal line 512. For example, the lower portion 211 of the first metal line 511 and the lower portion 212 of the second metal line 512 may be made of or contain Ru of more than 99 at. % and in one embodiment more than 99.9 at. % and with a first impurity level of less than 1 at. % and in one embodiment less than 0.1 at. %.

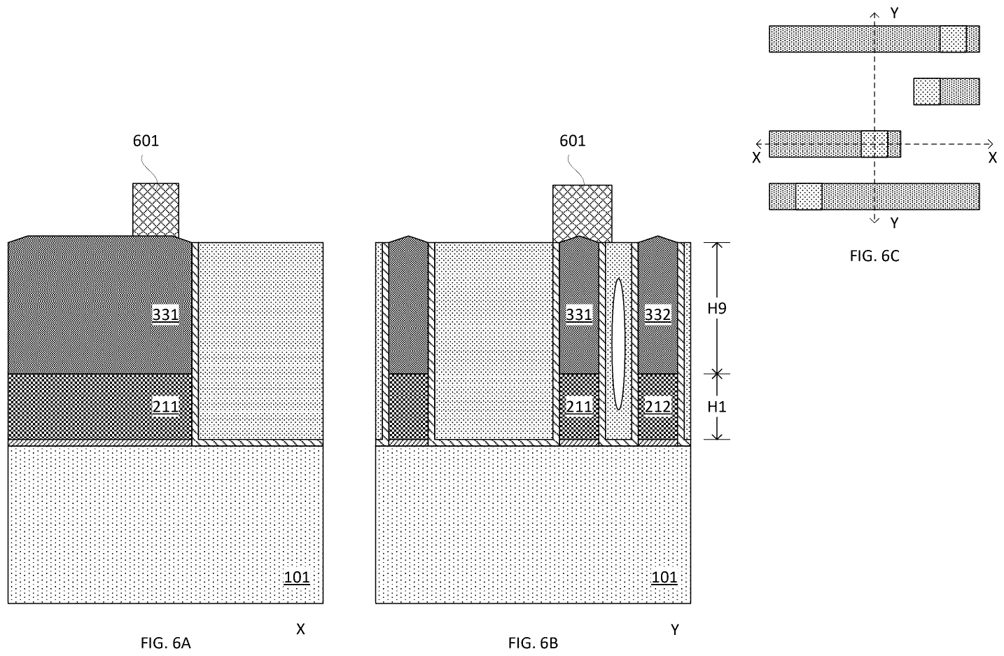

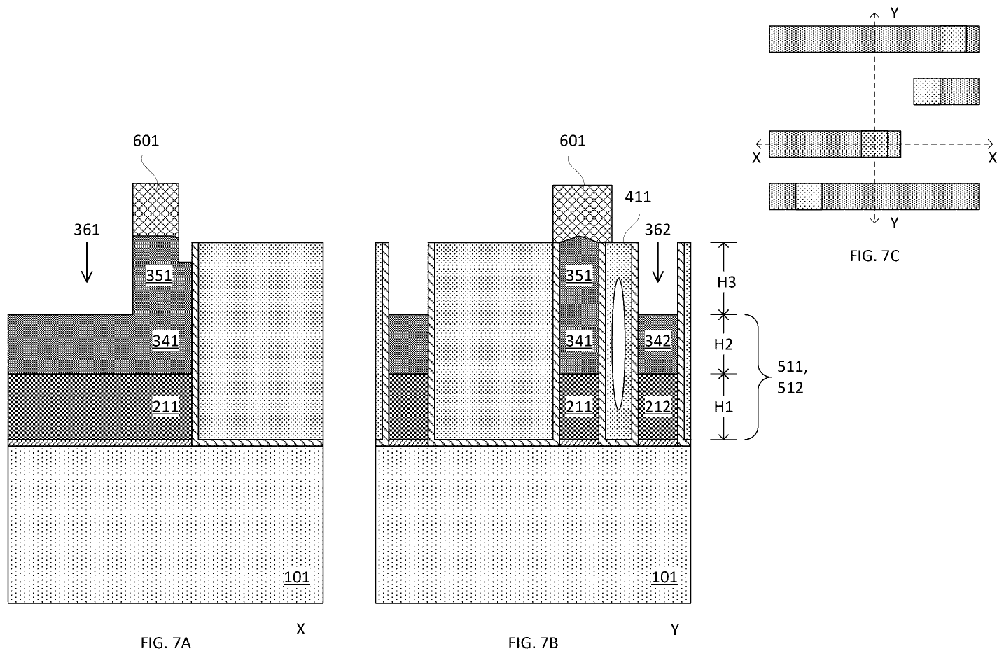

FIGS. 6A and 6B are demonstrative illustrations of cross-sectional views and FIG. 6C is a simplified top view of an interconnect structure in a step of manufacturing thereof according to one embodiment of present invention. More particularly, embodiments of present invention provide, following the step illustrated in FIGS. 5A, 5B, and 5C, applying a portion of the raw upper portion of the one or more metal lines to form one or more topvias. For example, embodiments of present invention provide forming a hard mask 601 on top of a portion of the raw upper portion 331 of the first metal line 511 for forming a topvia 351 (see FIG. 7A). As is illustrated, the hard mask 601 may fully cover the raw upper portion 331 in the width direction of the first metal line 511, but may cover only a portion, as is illustrated in FIG. 6A, of the raw upper portion 331 in the length direction of the first metal line 511.

FIGS. 7A and 7B are demonstrative illustrations of cross-sectional views and FIG. 7C is a simplified top view of an interconnect structure in a step of manufacturing thereof according to one embodiment of present invention. More particularly, following the step illustrated in FIGS. 6A, 6B, and 6C, embodiments of present invention provide, with the hard mask 601 covering a portion of the raw upper portion 331 of the first metal line 511, recessing the rest of the raw upper portion 331 of the first metal line 511 to create a first recess 361, thereby forming an upper portion 341 of the first metal line 511. Embodiments of present invention may also recess the raw upper portion 332 of the second metal line 512 to create a second recess 362, thereby forming an upper portion 342 of the second metal line 512. The upper portion 341 of the first metal line 511 and the upper portion 342 of the second metal line 512 may have a thickness H2 (or height). The thickness H2 may be between 10 nm and 50 nm, for example, and in one embodiment may between 40 nm and 50 nm. The first metal line 511 and the second metal line 512 may form an opening or gap therein-between that is filled with a lower portion of the isolation layer 411, and the opening or gap may have an aspect ratio, as measured by (H1+H2)/W, as high as about 15.

The remaining portion of the raw upper portion 331 of the first metal line 511 may be formed into a topvia 351 with a height H3, measured from the top surface of the upper portion 341 of the first metal line 511 to the top surface of the topvia 351. In one embodiment the topvia 351 may have a height equal to or larger than 10 nm such as, for example, 50 nm. The first metal line 511, which includes the lower portion 211 and the upper portion 341, may be separated by the isolation layer 411 from the second metal line 512, which includes the lower portion 212 and the upper portion 342. The topvia 351 has a top surface that is higher than a top surface of the upper portion 341 of the first metal line 511 and higher than a top surface of the upper portion 342 of the second metal line 512.

As being made clear from the above process, sidewalls of the lower portions 211 and 212 of the first and the second metal line 511 and 512 may be vertically aligned with sidewalls of the upper portions 341 and 342 of the first and the second metal line 511 and 512.

By combining a PVD process, which forms the lower portions 211 and 212 of the first and the second metal line 511 and 512, with a CVD process, which forms the upper portions 341 and 342 of the first and the second metal line 511 and 512, embodiments of present invention provide a process that is capable of forming metal lines with gaps or openings therein-between where the gaps or openings may have a high aspect ratio measured as (H1+H2)/W. For example, the aspect ratio of the gaps or openings may be as high as around 15. The process may also form a topvia on top of the metal lines with even higher aspect ratio of the gaps, measured as (H1+H2+H3)/W. For example, the aspect ratio of the gaps or openings adjacent to a topvia may be as high as around 20. In the meantime, metal lines formed through this process may still be able to maintain a relative low resistance by the fact that at least the lower portions of the metal lines are formed through a PVD process that generally have low resistance.

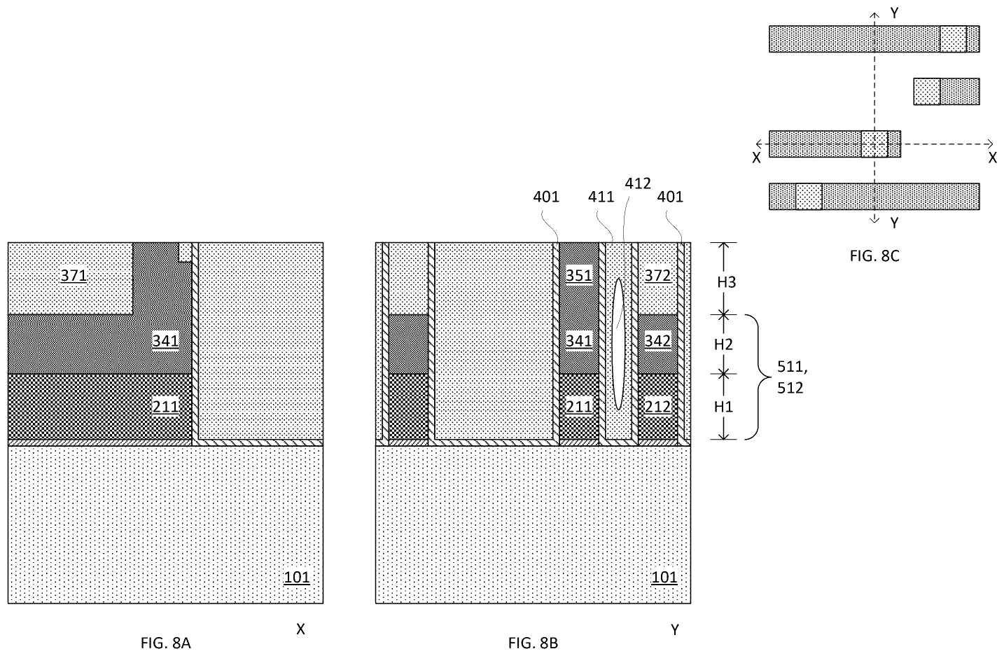

FIGS. 8A and 8B are demonstrative illustrations of cross-sectional views and FIG. 8C is a simplified top view of an interconnect structure in a step of manufacturing thereof according to one embodiment of present invention. More particularly, following the step illustrated in FIGS. 7A, 7B, and 7C, embodiments of present invention provide filling the openings created by the recessing of the raw upper portions of the one or more metal lines with a dielectric material. For example, the hard mask 601 may be lifted through an ash process. The first recess 361 above the upper portion 341 of the first metal line 511 may be filled with a dielectric material to form a dielectric layer 371 and the second recess 362 above the upper portion 342 of the second metal line 512 may be filled with a dielectric material to form a dielectric layer 372. Subsequently, a CMP process may be applied to planarize top surfaces of the dielectric layers 371 and 372 such that the top surfaces of the dielectric layers 371 and 372 may be co-planar with a top surface of the topvia 351.

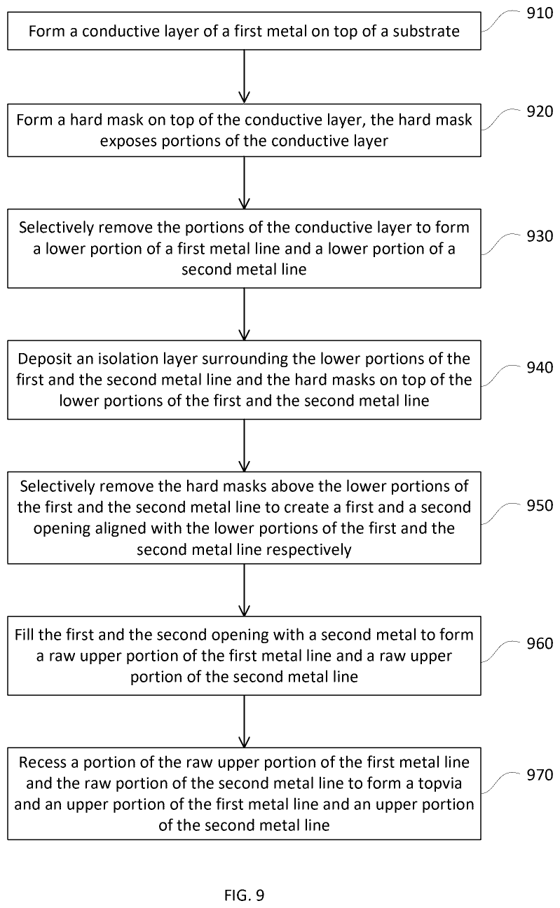

FIG. 9 is a demonstrative illustration of a flow-chart of a method of manufacturing an interconnect structure according to embodiments of present invention. The method includes (910) providing a substrate and forming a conductive layer of a first metal on top of the substrate; (920) forming a hard mask on top of the conductive layer where the hard mask exposes portions of the conductive layer; (930) selectively removing the portion of the conductive layer exposed by the hard mask to form a lower portion of a first metal line and a lower portion of a second metal line; (940) depositing an isolation layer surrounding the lower portions of the first and the second metal line and the hard masks on top of the lower portions of the first and the second metal line; (950) selectively removing the hard masks above the lower portion of the first and the second metal line to create a first and a second opening aligned with the lower portions of the first and the second metal line respectively; (960) filling the first and the second opening with a second metal to form a raw upper portion of the first metal line and a raw portion of the second metal line; and (970) recessing a portion of the raw upper portion of the first metal line and the raw portion of the upper portion of the second metal line to form a topvia and an upper portion of the first metal line and an upper portion of the second metal line.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. An interconnect structure comprising:
a metal line having a lower portion and an upper portion of different material composition, sidewalls of the lower portion of the metal line being vertically aligned with sidewalls of the upper portion of the metal line; and
a dielectric liner lining the sidewalls of the lower portion of the metal line and the sidewalls of the upper portion of the metal line.

2. The interconnect structure of claim 1, wherein the lower portion of the metal line comprises ruthenium of more than 99 at. % with a first impurity level and the upper portion of the metal line comprises ruthenium of more than 95 at. % but less than 99 at. % with a second impurity level, wherein the second impurity level is larger than the first impurity level.

3. The interconnect structure of claim 2, wherein the lower portion of the metal line is formed by a physical vapor deposition (PVD) process and the upper portion of the metal line is formed by a chemical vapor deposition (CVD) process.

4. The interconnect structure of claim 1, further comprising a dielectric layer covering a top surface of the upper portion of the metal line, sidewalls of the dielectric layer being vertically aligned with the sidewalls of the upper portion of the metal line, wherein the dielectric liner lines the sidewalls of the dielectric layer.

5. The interconnect structure of claim 4, further comprising a topvia on top of the upper portion of the metal line, wherein the topvia has a same material composition as the upper portion of the metal line and has a top surface that is co-planar with a top surface of the dielectric layer.

6. The interconnect structure of claim 5, wherein the metal line is a first metal line, further comprising a second metal line separated from the first metal line by an isolation layer, wherein the isolation layer has a top surface that is co-planar with the top surface of the topvia and has an aspect ratio of height over width that ranges from about 15 to about 20.

7. The interconnect structure of claim 6, wherein the isolation layer has a width equal to or less than 10 nm; the lower portion of the first metal line has a thickness between about 80 nm and about 100 nm; the upper portion of the first metal line has a thickness between about 40 nm and about 50 nm; and the topvia has a height larger than 10 nm.

8. The interconnect structure of claim 6, wherein the isolation layer includes an airgap.

9. A method of forming an interconnect structure comprising:
forming a conductive layer of a first metal on top of a substrate;
patterning the conductive layer into a lower portion of a first metal line and a lower portion of a second metal line;
creating a first and a second opening aligned respectively with the lower portion of the first metal line and the lower portion of the second metal line; and
filling the first and the second opening with a second metal to form a raw upper portion of the first metal line and a raw upper portion of the second metal line.

10. The method of claim 9, further comprising:
recessing a portion of the raw upper portion of the first metal line to form an upper portion of the first metal line and a topvia on top of the upper portion of the first metal line; and
recessing a portion of the raw upper portion of the second metal line to form an upper portion of the second metal line.

11. The method of claim 10, further comprising:
forming a dielectric layer on top of the upper portion of the first metal line; and
planarizing a top surface of the dielectric layer to be co-planar with a top surface of the topvia.

12. The method of claim 9, wherein patterning the conductive layer comprises:
forming a hard mask on top of the conductive layer; and
selectively removing portions of the conductive layer not covered by the hard mask to form the lower portion of the first metal line and the lower portion of the second metal line.

13. The method of claim 12, wherein creating the first and the second opening comprises:
depositing an isolation layer on top of the substrate to surround the lower portion of the first metal line and the hard mask on top thereof and to surround the lower portion of the second metal line and the hard mask on top thereof;
selectively removing the hard mask above the lower portion of the first metal line to create the first opening; and
selectively removing the hard mask above the lower portion of the second metal line to create the second opening.

14. The method of claim 13, wherein depositing the isolation layer comprises forming an airgap inside the isolation layer between the first metal line and the second metal line.

15. The method of claim 12, further comprising:
forming a dielectric liner lining sidewalls of the lower portion of the first metal line and the hard mask on top thereof; and
lining sidewalls of the lower portion of the second metal line and the hard mask on top thereof.

16. An interconnect structure comprising:
a first metal line having a lower portion and an upper portion of different material composition, sidewalls of the lower portion of the first metal line being vertically aligned with sidewalls of the upper portion of the first metal line;
a second metal line having a lower portion and an upper portion of different material composition, sidewalls of the lower portion of the second metal line being vertically aligned with sidewalls of the upper portion of the second metal line;
a dielectric liner lining sidewalls of the lower portion and the upper portion of the first metal line and lining sidewalls of the lower portion and the upper portion of the second metal line; and
an isolation layer between the first metal line and the second metal line, the isolation layer including an airgap.

17. The interconnect structure of claim 16, further comprising a topvia on top of the upper portion of the first metal line, wherein the topvia has a same material composition as the upper portion of the first metal line.

18. The interconnect structure of claim 17, further comprising a dielectric layer covering a top surface of the upper portion of the first metal line, wherein sidewalls of the dielectric layer are vertically aligned with the sidewalls of the upper portion of the first metal line, and a top surface of the dielectric layer is co-planar with a top surface of the topvia.

19. The interconnect structure of claim 18, wherein the isolation layer has a top surface co-planar with the top surface of the topvia and an aspect ratio of height over width ranging from about 15 to about 20, wherein the isolation layer has a width equal to or less than 10 nm; the lower portion of the first metal line has a thickness between about 80 nm and about 100 nm; and the upper portion of the first metal line has a thickness between about 40 nm and about 50 nm.

20. The interconnect structure of claim 16, wherein the lower portion of the first metal line comprises ruthenium with a first impurity level and the upper portion of the first metal line comprises ruthenium with a second impurity level, the second impurity level being larger than the first impurity level.
